(19) United States
(12) Patent Application Publication
(10) Pub. No.: US 2021/0108970 A1
(43) Pub. Date: Apr. 15, 2021

(54) THERMISTOR HOUSING

(71) Applicant: JOHNSON CONTROLS FIRE PROTECTION LP, Boca Raton, FL (US)

(72) Inventors: John B. STOWELL, Hollis, NH (US); James T. ROBERTS, Amherst, NH (US)

(21) Appl. No.: 16/599,763

(22) Filed: Oct. 11, 2019

(51) Int. Cl. G01K 1/08; G01K 7/22; H01C 1/02; H05K 7/14; H05K 1/18; G08B 19/00; G08B 17/06

(52) U.S. Cl. CPC G01K 1/08; G01K 7/22; H01C 1/02; H05K 7/1427; H05K 2201/10022; G08B 19/00; G08B 17/06; H05K 2201/10151; H05K 1/181

(57) ABSTRACT

A thermistor housing assembly for simplifying manual installation of a thermistor into a heat or smoke/hear detector.

### BACKGROUND

Many smoke detectors work by allowing air, including smoke and other particulates, from the surrounding environment into a chamber. The chamber has a light source and a light sensor. Depending on the type of smoke detector, smoke within the chamber may be detected by the scattering of light from the light source by particulates within the chamber, or by obfuscation of light from the light source.

Many heat detectors use a device, typically a thermistor, whose characteristics change with temperature.

Combination detectors combine various sensors into a single detector. In such detectors, the current amount of smoke, the rate of change of smoke, the temperature and the rate of change in temperature may all or in part be used to determine the presence of a fire.

In the assembly of smoke sensor/detector, a thermistor is typically fed manually through the chamber base and hand-soldered to a printed circuit board (PCB). Although inefficient, this is possible because the current thermistor is robust and has sufficient mass to be manipulated during assembly.

FIG. 1A is an exploded view of an existing combination smoke and heat detector. A light source 152, light sensor 154 and thermistor 156 are mounted onto a chamber base 150 and electrically connected to a printed circuit board (PCB) under the base 150. A light source holder 153 to keep the light source 152 pointed in correct direction is also mounted to the base 150. A smoke chamber cover 158 snaps onto the base 150, and the thermistor 156 is fed through a hole 162 in the smoke chamber cover 158. A detector cover 160 is then mounted over the detector assembly (all the parts just described) and the thermistor passes through a hole 164 in the detector cover 160 so it is exposed to the environment. A small cage 165 around the thermistor protects it from any moving objects that could damage it.

The thermistor 156 is a critical component, but the current hand-assembly process needed to install it is highly inefficient. As FIGS. 1B and 1C illustrate, the thermistor leads are manually guided around boss 157 and then hand-fed through small holes, on the order of 0.040″ diameter, in the chamber base. The thermistor leads are then blindly fed into PCB solder holes. After insertion of the leads through PCB solder holes, the thermistor must be manually manipulated to obtain the correct distance of the thermistor from the base, after which it is then hand-soldered to the PCB 172. This assembly process is feasible because this thermistor 156 and its leads are relatively robust and have sufficient mass to be manipulated as described above during assembly. This assembly process takes approximately 1 to 1.5 minutes, constituting about 30% of the total cycle time.

### SUMMARY

Due to a change in regulatory requirements, new sensors and detectors must use an even more sensitive thermistor, such as an NTC 226K thermistor, to meet the new standard. The new thermistor component may be much smaller and delicate, and more difficult to work with in high-volume production than the currently used thermistor. Without the new housing described herein, the bottleneck in the production/assembly process would be expected to become even more severe than it already is. The annual demand for sensors and detectors using this new thermistor may be in the millions, leading to millions of minutes of production inefficiency annually.

Since the new thermistor component is much smaller and more delicate, the current assembly process is neither efficient, viable, nor repeatable, especially in high-volume production. The novel thermistor housing described herein effectively addresses these problems. The thermistor housing makes the thermistor itself more robust without diminishing performance, reduces assembly cycle times, is self-retaining in the chamber base for soldering, and creates a more repeatable and accurate assembly process. It also improves the process flow and cycle time of a high-volume product. Without the thermistor housing described herein, there is a large risk of high levels of defects caused during the assembly process, creating a bottleneck that could affect the ability to meet demand. The thermistor housing makes the assembly process scalable to the level needed to meet demand, and could even make assembly with the older, larger thermistor more efficient.

The thermistor housing has a number of critical features, described in more detail herein. The design incorporates features that protect the thermistor without reducing functionality, and that improve the ease of assembly into mating components. The housing has been designed to consistently prepare thermistors for assembly by controlling the height of the thermistor and the separation distance of the leads. This is a critical achievement because the manual labor needed to prepare the thermistor by hand would create a significant bottleneck in the assembly process. The thermistor housing reduces assembly cycle time, creates a repeatable assembly process, and makes the thermistor itself more robust.

In testing, prototypes of the thermistor housing reduced assembly cycle times, the number of defects during assembly, and the scrap rate during assembly. Furthermore, a consistent and repeatable assembly process has been achieved.

Accordingly, an embodiment of a housing assembly for holding a component may have two parts wherein a first part has a crimp clearance region into which a deformable section on the second part may be displaced to secure the component leads such that the component is fixed in the housing. The housing assembly may be configured to be mounted onto a base.

The housing assembly may further include a crush rib configured to retain the component to the base.

Either part of the housing assembly may include component lead channels/grooves, wherein the other part of the housing assembly has matching component lead ribs that mate with the lead channels when the first and second parts are assembled together. Both housing assembly parts may include partial lead guides such that when the housing parts are assembled together, the partial lead guides of one part mate with the partial lead guides of the other part to form fully formed lead guides for guiding the component leads into the component lead channels. The component lead channels may be configured to direct leads of the component to a printed circuit board.

Furthermore, in an embodiment, the housing assembly may be keyed so that it can only be installed onto a chamber base in specific orientations. For example, the housing assembly may have at least one flat side and one rounded side.

In a further embodiment, the housing assembly may further include at least one guide peg configured to be inserted into corresponding holes in a printed circuit board (PCB). The pegs may extend beyond the component leads to protect the component leads from being damaged and help to align the component leads with corresponding thru-holes on the PCB. Additionally, the housing assembly may have a predetermined length to hold the component at a predetermined distance from the base.

In an embodiment, the component may be a thermistor.

An embodiment of a thermistor sub-assembly may include a housing assembly comprising a first housing part and a second housing part, as well as a thermistor secured in place in the housing assembly.

A hazard detector, according to an embodiment of the present invention, may include a housing assembly having first and second parts. One of the parts may comprise a deformable section, while the other part includes a crimp clearance region into which the deformable section may be displaced to secure component leads such that the component, for example a thermistor, is fixed in the housing to form a component housing assembly. The component housing assembly may be configured to be mounted onto a base, wherein at least one of the housing parts has a crush rib configured to hold the component housing assembly in place on the base. A printed circuit board (PCB) may be located behind and proximate to the base, wherein the component housing assembly and the base direct component leads through the base to predetermined thru-holes in the PCB. The housing assembly may have a predetermined length wherein when it is mounted onto the base, the component is a predetermined distance from the base, such that the component protrudes through a hole in a detector cover. The hazard detector may be, for example, a combination smoke and heat detector.

According to an embodiment, a method for assembling a thermistor sub-assembly may include attaching a first housing part to a second housing part to form a thermistor housing, at least one of the first and second parts comprising at least one plastic plug, and the other of the first and second parts comprising a corresponding hole for each plastic plug, each plug extending through its corresponding hole. The thermistor's leads may then be inserted into the thermistor housing. The plastic plugs may then be cold-staked to secure the two housing parts to each other. The thermistor leads may be secured to the thermistor housing by deforming at least one deformable section of one part into a crimp clearance section of the other part.

Alternatively, a method for assembling a hazard detector having a detector sensor and a base may include assembling a component sub-assembly having a crush rib on the sub-assembly's outer surface. The component sub-assembly may then be inserted into the base, wherein the crush rib secures the component sub-assembly the base.

### BRIEF DESCRIPTION OF THE DRAWINGS

FIG. 1A is an exploded view of an existing combination smoke and heat detector.

FIGS. 1B and 1C are drawings illustrating how a thermistor is manually inserted into a chamber base in the prior art.

FIG. 2 is a drawing illustrating several features of the thermistor housing assembly.

FIGS. 3A, 3B and 3C are respectively top, side and perspective views of a first part of the thermistor housing assembly.

FIGS. 4A, 4B and 4C are respectively top, side and perspective views of a second part of the thermistor housing assembly.

FIG. 5 is a detailed drawing illustrating the crimping feature of the thermistor housing assembly.

FIG. 6 is a detailed drawing illustrating the crush rib locking mechanism and a cold-staked boss of thermistor housing assembly.

FIG. 7 is a drawing of the chamber base, in particular illustrating, in an embodiment, the relative locations of some of the components.

FIG. 7A is a detailed drawing of the mounting hole in the chamber base for mounting the thermistor housing assembly.

FIG. 8 is a side cutaway view of the chamber base with PCB.

FIGS. 9A and 9B are drawings illustrating use of the guiding pins to guide the thermistor housing assembly in a specific orientation.

FIGS. 9C and 9D are drawings illustrating placement of the thermistor leads when the thermistor housing assembly has been inserted into the mounting hole of FIG. 7A.

FIG. 10 is an exploded view of a combination smoke and heat detector employing an embodiment of the thermistor housing assembly.

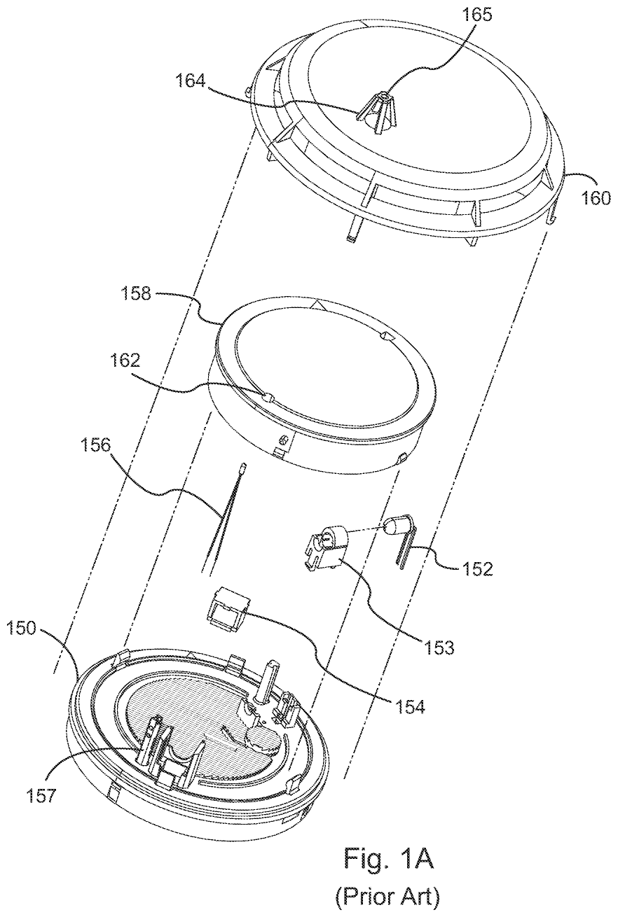

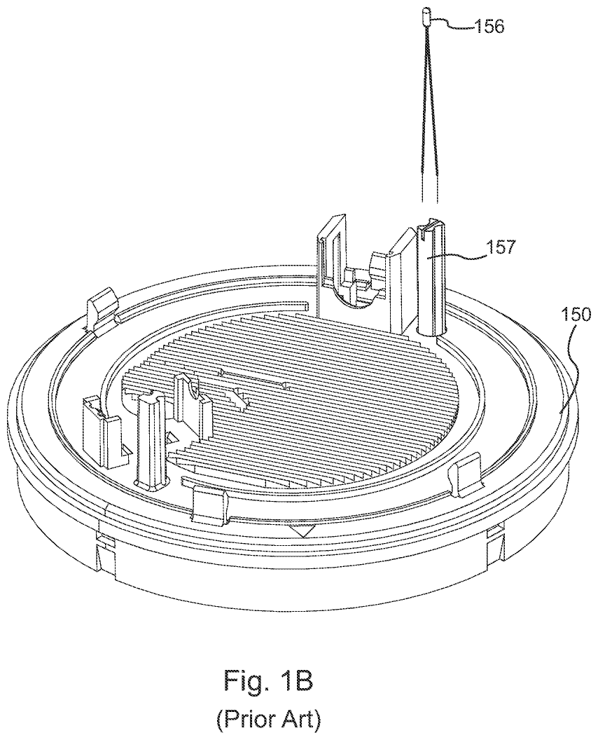

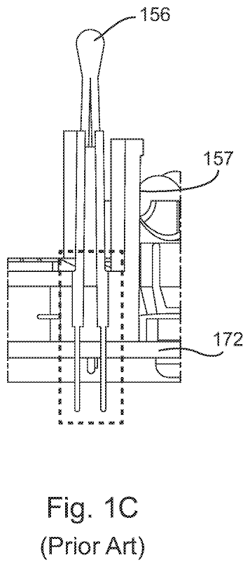

### DESCRIPTION

Manually placing an electrical component such as a thermistor is not a very efficient process and is prone to mistakes. For smaller and more delicate thermistors, the current assembly process is even less efficient, less viable, and less repeatable, especially in high-volume production. The thermistor housing described herein addresses this problem with many novel features.

The thermistor housing makes the thermistor itself more robust without diminishing performance, reduces assembly cycle times, is self-retaining in the chamber base for soldering, and creates a more repeatable and accurate assembly process.

The thermistor housing improves the manufacturing process flow and cycle time of a high volume product. Without the thermistor housing, there is a large risk of high numbers of defects caused during the assembly process, creating a bottleneck that could affect the ability to meet demand. The thermistor housing makes the assembly process scalable to the level needed to meet demand.

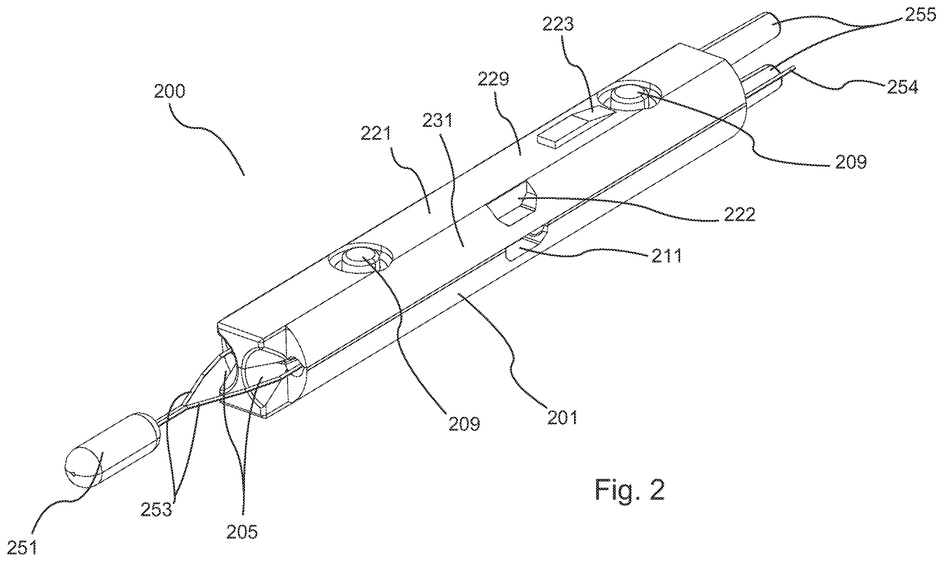

FIG. 2 is a drawing illustrating several important features of the thermistor housing. Many of these features protect the thermistor without reducing functionality, and improve the ease of assembly into mating components. The housing 200 has been designed to consistently prepare the thermistor 251 for assembly by, for example, maintaining a consistent height of the thermistor 251 and the separation distance between the leads 253. This is a critical achievement because the manual labor needed to prepare the thermistor free-hand can create a significant bottleneck in the assembly process.

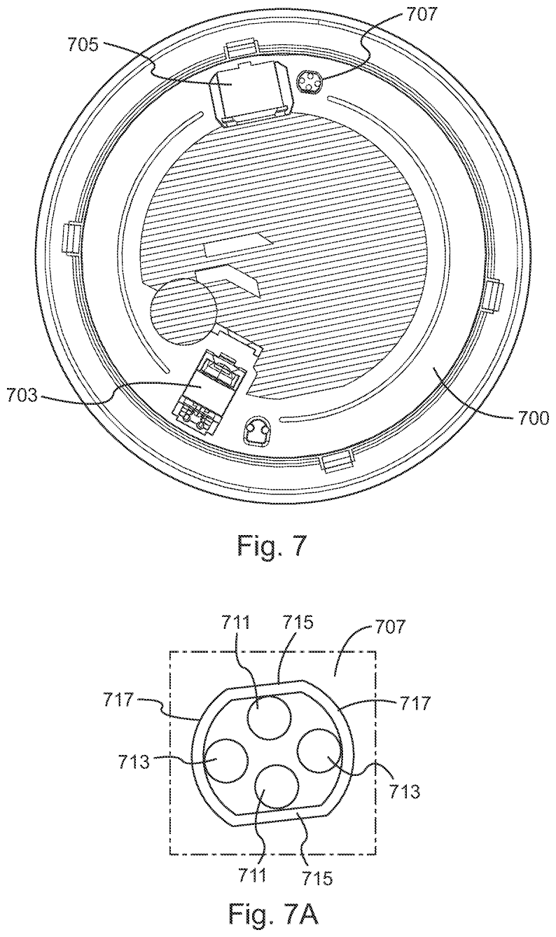

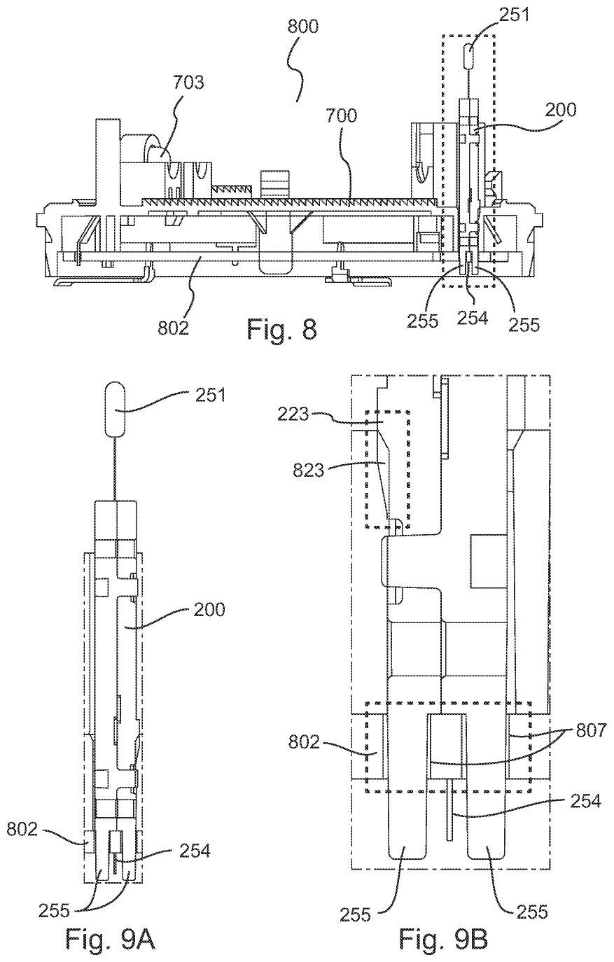

The housing 200 is formed by assembling two mating parts: a first housing part 201 and a second housing part 221. When assembled together, these two housing parts 201, 221 combine to form two wedge-shaped funnels 205 at one end of the housing that receive the thermistor leads 253 and serve to separate the leads to the proper spacing for PCB assembly. The leads are conducted through the housing 200 and the ends of the leads (only one lead end shown at 254) protrude out the other end of the housing 200. Protective guide pegs 255 protect the thermistor lead ends 254 and guide the housing through the chamber base (FIG. 7, ref. 700), aligning the leads to the intended thru-holes in the PCB (FIG. 8, ref. 802).

Plastic bosses 209 may be cold-staked, locking the two halves of the housing together. Once the thermistor 251 is inserted into the housing 200, wire crimping features (one for each lead) 222 on the second housing part 221 are distorted into matching crimping spaces 211 on the first housing part 201, securing the thermistor leads 253 and the thermistor 251 to the housing 200 and setting the proper height of the thermistor. Conversely, the thermistor may be inserted into the housing 200 and the cold-staking and crimping may be performed simultaneously.

A crush rib 223 allows the thermistor housing to be self-retaining in the chamber base.

As can be seen in FIG. 2, the housing 200 may have a flat surface 229 and a rounded surface 231. This allows the housing 200 to be keyed into a mounting hole on the chamber base such that it can only be inserted in certain orientations so that the thermistor leads will line up with the proper PCB holes behind the chamber base. In the case of a non-polarized electrical component such as thermistor, both housing parts 201, 221 may have matching round and flat sections so that the housing 200 may easily be inserted in either of two orientation, 180 degrees apart. In the case where a component housing holds a polarized component such as a diode, LED or electrolytic capacitor, the housing could be keyed such that it may only be inserted in a single orientation.

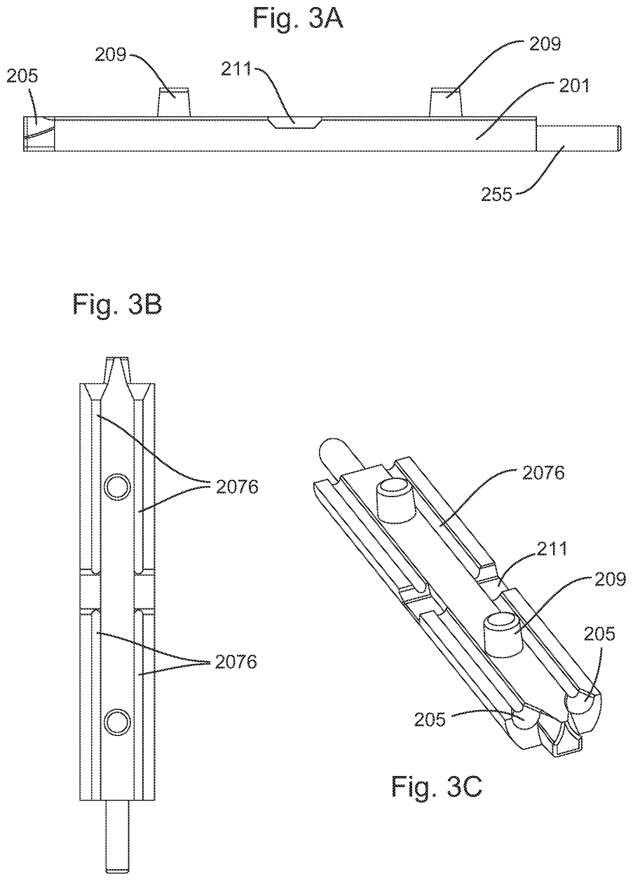

FIGS. 3A, 3B and 3C illustrate respectively side, top and perspective views of a first part 201 of the housing assembly, illustrating the press-fit bosses 209, a first protective guide peg 255, thermistor lead channels (grooves) 207, crimp clearances 211 and thermistor lead guides 205.

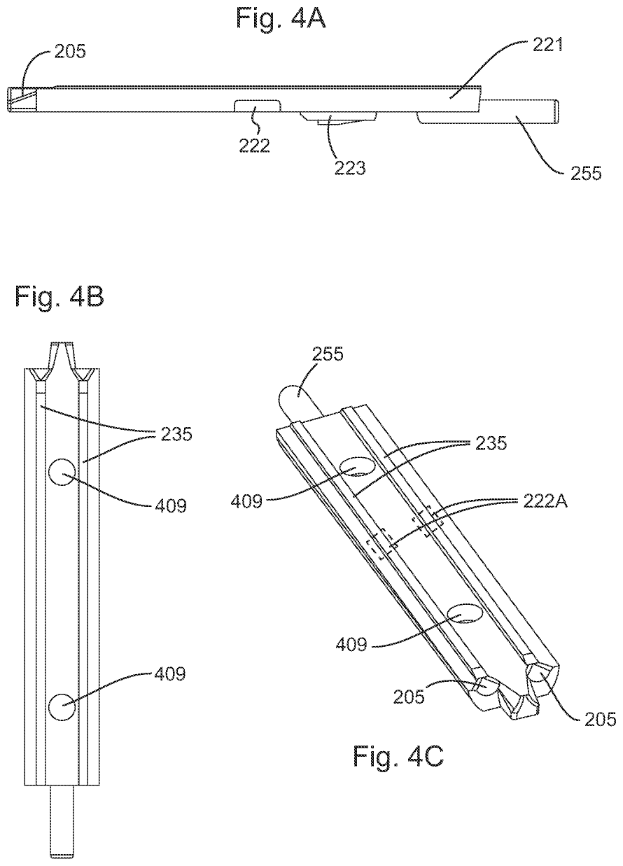

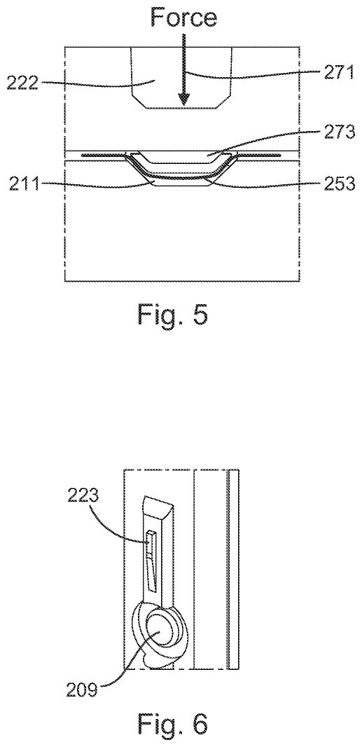

FIGS. 4A, 4B and 4C illustrate respectively side, bottom and perspective views of a second part 221 of the housing assembly that mates with the first part 201, showing the press-fit boss holes 409, a second protective guide peg 255, thermistor lead ribs 235 that mate with the thermistor lead channels 207 to hold the thermistor leads and thermistor lead guides 205. Once the two parts 201, 221 are assembled together and the thermistor inserted therein, crimp sections 222 (only one shown) may be deformed the into the crimp clearance region 211, locking the thermistor's leads within the lead grooves/channels 207 (see FIG. 5 for more detail).

When the thermistor housing assembly is placed into the mounting hole (see FIG. 7A), a crush rib 213 is crushed inward by the wall of the mounting hole, virtually locking the housing assembly in place. Although the crush rib 213 is shown on the second housing part 221, it could instead be on the first housing part 201. Furthermore, the housing assembly is not limited to a single crush rib.

FIG. 5 is a detailed drawing illustrating how the crimping feature secures the thermistor to the thermistor housing assembly. In an embodiment, at the same time as the cold-staking operation, the deformable crimping region 222 may be displaced, in the direction of arrow 271 into the crimping region 211. The deformed plastic 273 thus clamps down on the thermistor leads 253 to secure the thermistor to the housing.

FIG. 6 provides a detailed view illustrating the crush rib locking mechanism 223 of the thermistor housing assembly. The rib 223 is a small rib located on one (or more) surfaces of the thermistor housing assembly. When the thermistor housing assembly is inserted into the mounting hole with a small amount of force, the surface of the mounting hole crushes the rib 223, creating sufficient friction to prevent the housing assembly from falling out as the chamber base is manipulated.

FIG. 7 is a drawing of a chamber base 700 for use with the thermistor housing assembly, illustrating, in an embodiment, the relative locations of some of the components, specifically, a light source assembly 703, a photodetector 705 and a thermistor housing assembly mounting hole 707.

FIG. 7A is a detailed drawing of the mounting hole 707. In the embodiment shown, the mounting hole has two flat sides 715 and two rounded sides 717 to match the shape of the housing assembly such that the housing may only be installed in one of two orientations as discussed previously, guaranteeing that the thermistor leads are correctly placed to pass through corresponding solder holes in the PCB behind the chamber base 700. This is further accomplished by a pair of holes 711 for receiving the guiding pins 255 and two holes 713 through which the thermistor lead ends 254 may pass. As noted earlier, the mounting hole could be keyed in various other ways to require only a single orientation of the assembly, using any combination of, for example, shape of the mounting hole, various guiding pin shapes, sizes and/or a different number and pattern of guiding pins.

FIG. 8 is a side cutaway view 800 of an embodiment having a chamber base with a PCB 802 mounted behind the chamber base 700. Here it can be seen that the thermistor 251 is mounted to the housing 200 and that the lead ends 254 of the thermistor 251 pass through to the PCB 802, to which they may be hand-soldered. This view also shows the guiding pins 255.

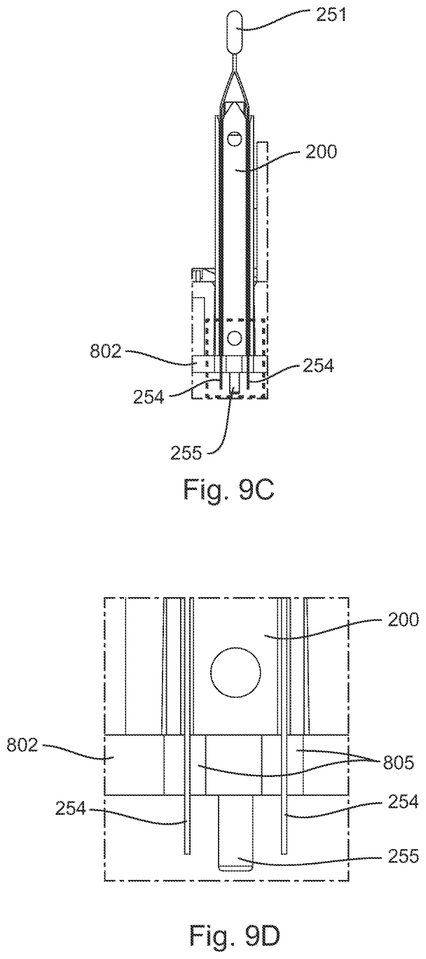

FIGS. 9A and 9B are drawings illustrating use of the guiding pins to guide the thermistor housing assembly in a specific orientation. In particular, holes 807 in the PCB 802 through which the guiding pins pass 255 are shown. Also illustrated in FIG. 9B is the crush rib 223 after it has been crushed by the wall 823 of the mounting hole 707.

Similar to FIGS. 9A and 9B, FIGS. 9C and 9D illustrate the placement of the thermistor leads when the thermistor housing assembly has been inserted into the mounting hole of FIG. 7A through PCB holes 805.

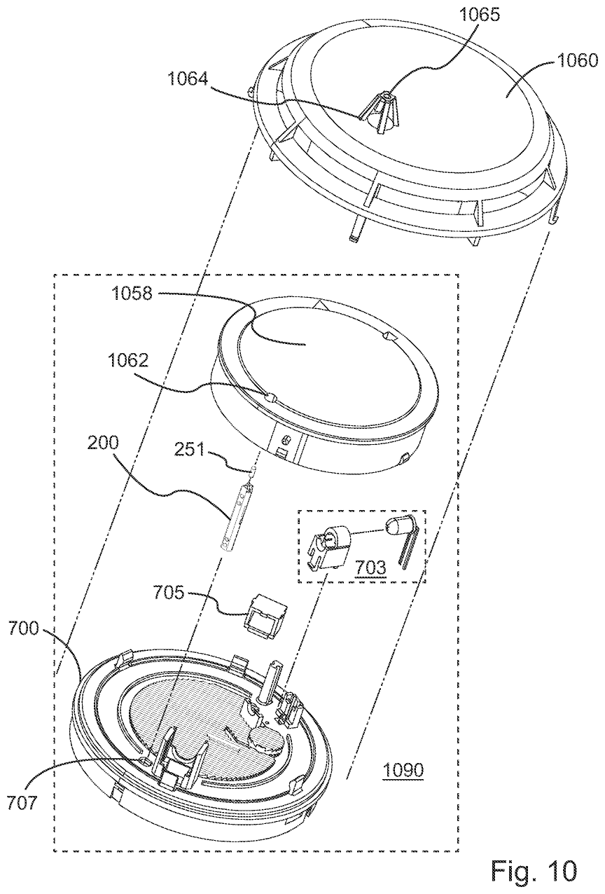

FIG. 10 is an exploded view of a combination smoke and heat detector employing an embodiment of the thermistor housing assembly. The light source assembly 703 of FIG. 7 comprises a light source and light source holder. A light sensor 705 is also mounted onto the chamber base. Thermistor housing assembly 200 with thermistor 251 installed thereon is also mounted to the chamber base 150 at mounting hole 707. The light source, light sensor and thermistor are each electrically connected, e.g., soldered, to the printed circuit board (PCB) 802 behind the base 150 (see FIG. 8). A smoke chamber cover 1058 snaps onto the base 700. A detector cover 1060 may then be attached to the chamber assembly (all the parts just described, collectively 1090). The thermistor 251 passes through a hole 1062 in the detector cover 1058 so it is exposed to the environment. A detector cover 1060 may then be snapped onto the chamber base, and the thermistor protrudes through a hole 1064 in the detector cover 1060. A small cage 1065 around the thermistor 251 protects it from any objects that could damage it.

There are various methods of assembly that can utilize the thermistor housing.

For example, the two parts 201 and 221 may first be assembled together to form the housing assembly. The thermistor 251 may then be inserted and secured in the housing as described above, and the completed thermistor subassembly 200 may then be plugged into the chamber base mounting hole 707.

Alternatively, the plastic housing may be assembled together, and then the housing alone may be plugged into the chamber base. The thermistor may then be fed into the housing which guides the leads through the PCB holes. In this case, of course, the cold staking and crimping would not be done simultaneously.

In yet another alternative, a single-piece housing may be molded around the leads of the thermistor. The over-molded assembly may then be plugged into the chamber base which guides the leads of the thermistor through the PCB holes.

It would be understood by one skilled in the art that while many of the features described herein are described as being on the first part 201 or the second part 221 of the housing, many of these features could be on the other part than that described. For instance, the crush rib 223 may be located on the first part 201 or the second part 221. For that matter, each part 201, 221 may have a crush rib. Further, it does not matter which part comprises a groove as long as the other part comprises a matching rib.

For clarification of claim terms, a “housing assembly” is an assembly of two or more parts that, when assembled together, are configured to hold an electrical component, such as (but limited to) a thermistor, LED, photosensor in place a predetermined distance away from a printed circuit board or base, such as a smoke chamber base. A “component housing assembly” is a housing assembly plus an electrical component installed therein. A “thermistor housing assembly” is a component housing assembly wherein the electrical component is a thermistor.

While the invention is illustrated in the drawings and described herein, this disclosure is to be considered as illustrative and not restrictive in character. The present disclosure is exemplary in nature and all changes, equivalents, and modifications that come within the spirit of the invention are included. The detailed description is included herein to discuss aspects of the examples illustrated in the drawings for the purpose of promoting an understanding of the principles of the invention. No limitation of the scope of the invention is thereby intended. Any alterations and further modifications in the described examples, and any further applications of the principles described herein are contemplated as would normally occur to one skilled in the art to which the invention relates. Some examples are disclosed in detail, however some features that may not be relevant may have been left out for the sake of clarity.

Singular forms “a”, “an”, “the”, and the like include plural referents unless expressly discussed otherwise. As an illustration, references to “a device” or “the device” include one or more of such devices and equivalents thereof.

Directional terms, such as “up”, “down”, “top” “bottom”, “fore”, “aft”, “lateral”, “longitudinal”, “radial”, “circumferential”, “behind”, etc., are used herein solely for the convenience of the reader in order to aid in the reader's understanding of the illustrated examples. The use of these directional terms does not in any manner limit the described, illustrated, and/or claimed features to a specific direction and/or orientation.

### REFERENCE NUMBERS

150 Chamber base (prior art)
152 Light source (prior art)
153 Light source holder (prior art)
154 Photosensor (prior art)
156 Thermistor (prior art)
157 Chamber base boss (prior art)
158 Chamber cover (prior art)
160 Detector cover (prior art)
162 Hole in chamber cover through which the thermistor 156 passes (prior art)
164 Hole in detector cover through which the thermistor 156 passes (prior art)
165 Cage for protecting the thermistor 156 (prior art)
172 Printed circuit board (PCB) (prior art)
200 Thermistor housing
201 First thermistor housing part
205 Wedge-shaped funnels for receiving the thermistor leads 253. Also referred to
207 Thermistor lead channels
209 Pre-fit bosses/pegs cold-staked to hold the two parts 201, 221 together to form a
211 Crimp space for the respective wire crimping feature 222
221 Second thermistor housing part
222 Wire crimping feature
223 Crush rib
229 Thermistor housing flat surface
231 Thermistor housing rounded surface
235 Thermistor lead rib
251 Thermistor
253 Thermistor leads
254 Thermistor lead ends
255 Protective guide pegs
271 Arrow showing the direction in which force is applied to the wire crimping
273 The deformed plastic resulting from applying force in the direction of arrow 271
409 Press-fit boss holes for receiving the bosses 209
700 Chamber base
703 Light source assembly
705 Photodetector
707 Thermistor housing assembly mounting hole
711 Chamber base holes for receiving guide pegs 255
713 Chamber base holes for receiving thermistor leads
715 Flat sides of mounting hole 707
717 Rounded sides of mounting hole 707
800 Cutaway view of the chamber base 700
802 Printed circuit board (PCB)
805 PCB holes through which thermistor leads pass
807 PCB holes through which PCB guide pegs pass
823 Wall of mounting hole 707
1058 Smoke chamber cover
1060 Detector cover
1062 Hole in smoke chamber cover through which the thermistor passes
1064 Hole in detector cover through which the thermistor passes
1065 Protective thermistor cage
1090 Chamber assembly

I claim:

1. A housing assembly for holding a component, the component having leads, comprising:
a first housing part; and
a second housing part;
wherein the second housing part comprises
a deformable section, and
wherein the first housing part comprises
a crimp clearance region into which the deformable section may be displaced to secure the component leads such that the component is fixed in the housing;
the housing assembly configured to be mounted onto a base.

2. The housing assembly of claim 1, wherein at least one of the housing parts comprises a crush rib configured to retain the component to the base.

3. The housing assembly of claim 1, wherein one of the first or second housing parts comprises component lead channels, and wherein the other housing part comprises component lead ribs that mate with the lead channels when the first and second parts are assembled together.

4. The housing assembly of claim 3, wherein the first part comprises first partial lead guides, the second part comprises second partial lead guides, wherein upon assembly of the housing assembly the first partial lead guides mate with the second partial lead guides to form two fully formed lead guides for guiding component leads into the component lead channels.

5. The housing assembly of claim 3, wherein the component lead channels are configured to direct leads of the component to a printed circuit board.

6. The housing assembly of claim 1, wherein the housing assembly is keyed so that it can only be installed on a chamber base in specific orientations.

7. The housing assembly of claim 6, wherein the housing assembly has at least one flat side and one rounded side.

8. The housing assembly of claim 1, further comprising:
at least one guide peg configured to be inserted into corresponding holes in a printed circuit board (PCB), the pegs further configured such that they extend beyond the component leads to protect the component leads from being damaged and help to align the component leads with corresponding thru-holes on the PCB.

9. The housing assembly of claim 1, wherein the housing assembly has a predetermined length to hold the component at a predetermined distance from the base.

10. The housing assembly of claim 1, wherein the component is a thermistor.

11. A thermistor sub-assembly, comprising:
a housing assembly comprising
a) a first housing part and
b) a second housing part; and
a thermistor secured in place in the housing assembly.

12. A hazard detector, comprising:
a housing assembly comprising:
a first housing part, and
a second housing part,
wherein at least one of the first and second housing parts comprises a crush rib;
a component having leads,
wherein the second housing part comprises a deformable section, and
wherein the first housing part comprises a crimp clearance region into which the deformable section may be displaced to secure the component leads such that the component is fixed in the housing to form a component housing assembly;
a base, the component housing assembly configured to be mounted onto the base, wherein at least one of the first and second housing parts comprises a crush rib configured to hold the housing assembly in place on the base;
a printed circuit board (PCB) behind and proximate to the base, wherein the component housing assembly and the base are configured to direct the component leads through the base to predetermined thru-holes in the PCB; and
a detector cover, the housing assembly having a predetermined length wherein when the housing assembly is mounted onto the base, the component is a predetermined distance from the base, the predetermined length sufficient for the component to protrude through a hole in the detector cover.

13. The hazard detector of claim 12, wherein the component housing assembly further comprises at least one guide peg configured pass through corresponding holes in the base and corresponding holes in PCB, the pegs further configured such that they extend beyond the component leads to protect the component leads from being damaged and help to align the component leads with corresponding thru-holes on the PCB.

14. The hazard detector of claim 12, wherein the component is a thermistor.

15. The hazard detector of claim 12, wherein the hazard detector is a combination smoke and heat detector.

16. A method for assembling a thermistor sub-assembly, comprising:
attaching a first housing part to a second housing part to form a thermistor housing, at least one of the first and second parts comprising at least one plastic plug, and the other of the first and second parts comprising a corresponding hole for each of said at least one plastic plug, each said plug extending through its corresponding hole;
inserting a thermistor's leads into the thermistor housing;
cold-staking the plastic plugs; and
securing the thermistor leads to the thermistor housing by deforming at least one deformable section of at least one of the first and second housing parts into a hollow section of the other part.

17. The method of claim 16, wherein deforming a deformable section comprises crimping said deformable section.

18. A method for assembling a hazard detector, the hazard detector comprising a detector sensor and a base, the method comprising the steps of:
assembling a component sub-assembly, the sub-assembly including at least one crush rib on said sub-assembly's outer surface; and
inserting the component sub-assembly into the base, wherein the at least one crush rib secures the component sub-assembly the base.

19. The method of claim 18, wherein the step of assembling a component sub-assembly further comprises the steps of:
assembling first and second housing parts together to form a component housing;
cold staking at least one press-fit plug on one of the housing parts with a matching hole on the other matching part;
inserting leads of the component into the component housing; and
locking the component leads in place by crimping at least one deformable section of one of the parts comprises crimping into a hollow section of the other part.

20. The method of claim 18, wherein the hazard detector is a combination smoke and heat detector, and the component is a thermistor.
